(19) United States
(12) Patent Application Publication
(10) Pub. No.: US 2009/0261902 A1
(43) Pub. Date: Oct. 22, 2009

(54) Asynchronous Error Correction Circuit for Switching Amplifier

(75) Inventors: Pallab Midya, Palatine, IL (US); Matthew R. Miller, Arlington Heights, IL (US); Theresa Paulo, San Jose, CA (US); William J. Roeckner, Carpentersville, IL (US)

Correspondence Address: VEDDER PRICE/FREESCALE, 222 N. LASALLE STREET, CHICAGO, IL, 60601, US

(73) Assignee: Freescale Semiconductor, Inc., Austin, TX (US)

(21) Appl. No.: 12/104,874

(22) Filed: Apr. 17, 2008

(51) Int. Cl. H03F 3/217

(52) U.S. Cl. 330/251; 375/238

(57) ABSTRACT

A circuit (104, 106) includes a comparison circuit (202, 504, 506, 602) and a correction circuit (204, 508, 510, 604). The comparison circuit provides a comparison signal (212, 524, 526, 612) in response to an error value (210, 520, 522, 610) and a reference value (214). The error value is based on a pulse modulated input signal (114) and a pulse modulated output signal (118). The correction circuit asynchronously provides a corrected pulse modulated signal (116) by selectively delaying and advancing an edge of the pulse modulated input signal based on the comparison signal. The pulse modulated output signal is based on the corrected pulse modulated signal.

### BACKGROUND

1. Field

The present disclosure generally relates to switching amplifiers, and more specifically, to error correction in switching amplifiers.

2. Related Art

Digital audio switching power amplifiers are well known and widely used. Such amplifiers receive a digital audio signal which has been pulse modulated. Most high efficiency digital audio switching power amplifiers are based on pulse width modulation (PWM). PWM is widely used in a variety of applications such as digital audio amplifiers and control applications including motor controllers. Many of these applications convert a sampled digital signal to a digital pulse-width modulation signal in order to obtain high efficiency and high accuracy. The PWM signal is presented to a switching amplifier that performs a level shifting function to translate the digital PWM input signal to a digital PWM signal having significantly higher voltage levels. To accomplish the power amplification, a higher voltage power supply is used in which the power supply voltage is directly used as the digital logic one value. Because power supplies have noise coupled into the voltage, the noise becomes a source of error in the switching amplifier. The digital switching amplifier has no ability to reject the power supply noise. Practical implementations of a switching amplifier generate distorted output pulse signals. These distortions result in nonlinear amplification of the modulated output signal. Therefore, most switching amplifiers have both nonlinearity and power supply noise error. In addition, switching power amplifiers are known to generate electromagnetic interference. One known way to reduce the electromagnetic interference is to vary the switching frequency of the PWM signal.

In one method, digital correction circuitry is used to compensate for the nonlinearity and power supply noise error. However, this method requires an analog to digital conversion (ADC) circuit to convert an analog error correction signal into a digital error correction signal. Due to ADC circuit, this method is synchronous and therefore cannot properly compensate for nonlinearities and power supply noise errors of variable switching frequency PWM signals. Accordingly, there is a need for an error correction circuit that can compensate for nonlinearities and power supply noise errors of variable switching frequency PWM signals.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale.

FIG. 1 is an exemplary functional block diagram of an audio device that includes an asynchronous error correction circuit according to the present disclosure;

FIG. 2 is an exemplary functional block diagram of the asynchronous error correction circuit according to one embodiment of the present disclosure;

FIG. 3 is an exemplary functional block diagram of an error amplification circuit of the asynchronous error correction circuit according to one embodiment of the present disclosure;

FIG. 4, an exemplary functional block diagram of an error correction circuit of the asynchronous error correction circuit according to one embodiment of the present disclosure;

FIG. 5, an exemplary functional block diagram of the asynchronous error correction circuit according to another embodiment of the present disclosure;

FIG. 6 an another exemplary functional block diagram of the asynchronous error correction circuit according to another embodiment of the present disclosure;

FIG. 7 is an exemplary functional block diagram of the error amplification circuit according to one embodiment of the present disclosure; and

FIG. 8 is an exemplary functional block diagram of the error correction circuit according to one embodiment of the present disclosure.

### DETAILED DESCRIPTION

In one example, a circuit includes a comparison circuit and a correction circuit. The comparison circuit provides a comparison signal in response to an error value and a reference value. The error value is based on a pulse modulated input signal and a pulse modulated output signal. The correction circuit asynchronously provides a corrected pulse modulated signal by selectively delaying and advancing an edge of the pulse modulated input signal based on the comparison signal. The pulse modulated output signal is based on the corrected pulse modulated signal. In one example, the circuit is an integrated circuit.

The circuit provides, among other advantages, asynchronous error correction for nonlinearities and power supply noise errors of variable and fixed switching frequency pulse modulated signals. In addition, the circuit does not require an analog to digital converter circuit to compensate for nonlinearities and power supply noise errors. As such, the overall size of the circuit is reduced. Other advantages will be recognized by those of ordinary skill in the art.

In one example, the correction circuit transitions the corrected pulse modulated signal from a first logic state to a second logic state in response to the pulse modulated input signal and the comparison signal transitioning to a common logic state.

In one example, the correction circuit includes a latch circuit. The latch circuit delays or advances the edge of the pulse modulated input signal in response to the pulse modulated input signal and the comparison signal.

In one example, the correction circuit includes a first logic circuit and a second logic circuit. The first logic circuit is operatively coupled to a first input terminal of the latch circuit. The first logic circuit provides a first latch input signal when an input value of the pulse modulated input signal and the comparison signal are in a first logic state. The second logic circuit is operatively coupled to a second input terminal of the latch circuit. The second logic circuit provides a second latch input signal when the input value of the pulse modulated input signal and the comparison signal are in a second logic state that is complementary to the first logic state.

In one example, the latch circuit provides a rising edge of the corrected pulse modulated signal in response to the first input signal and a falling edge of the corrected pulse modulated signal in response to the second input signal. In one example, the error value is based on an integration value determined by integrating a difference between the pulse modulated input signal and the pulse modulated output signal.

In one example, the circuit includes an error amplification circuit. The error amplification circuit provides the error signal in response to the pulse modulated input signal and the pulse modulated output signal. In one example, the error value is based on an integration value determined by integrating a difference between the pulse modulated input signal and the pulse modulated output signal.

In one example, the circuit includes a switching amplifier circuit. The switching amplifier circuit provides the pulse modulated output signal in response to the corrected pulse modulated signal.

In one example, the circuit includes a second correction circuit. The second correction circuit asynchronously provides a second corrected pulse modulated signal by selectively delaying and advancing a second edge of the pulse modulated input signal based on the comparison signal. The second pulse modulated output signal is based on the second corrected pulse modulated signal.

In one example, the circuit includes an inverter circuit. The inverter circuit is operatively coupled between the correction circuit and the second correction circuit. The inverter circuit provides an inverted comparison signal to the second correction circuit in response to the comparison signal.

In one example, an audio device (e.g., digital media player, a compact disc player, or other suitable audio device) includes a conversion circuit, an error correction circuit, and a switching amplifier circuit. The conversion circuit provides a pulse width modulated signal in response to a pulse code modulated signal. The error correction circuit includes a comparison circuit and a correction circuit. The comparison circuit provides a comparison signal in response to an error value and a reference value. The error value is based on the pulse width modulated signal and a pulse width modulated output signal. The correction circuit asynchronously provides a corrected pulse width modulated signal by selectively delaying and advancing an edge of the pulse width modulated signal based on the comparison signal. The pulse width modulated output signal is based on the corrected pulse width modulated signal. The switching amplifier circuit provides the pulse width modulated output signal in response to the corrected pulse width modulated signal.

As used herein, the terms “circuit” and “module” can include one or more processors (e.g., shared, dedicated, or group of processors such as but not limited to microprocessors, DSPs, or central processing units) and memory that execute one or more software or firmware programs, electronic circuits, integrated circuits, combinational logic circuits, FPGAs, ASICs, state machines, and/or other suitable components that provide the described functionality. In addition, the term “signal” may refer to analog or digital information.

Referring now to FIG. 1, an audio device 100 such as a digital media player, a compact disc player, or other suitable audio device that drives a load such as a speaker using a pulse code modulated signal is depicted. The audio device 100 includes a pulse modulation conversion module 102, an asynchronous error correction circuit 104, and a switching amplifier circuit 106. In one embodiment, the asynchronous error correction circuit 104 and the switching amplifier circuit 106 can be included in an integrated circuit 108. In another embodiment, the asynchronous error correction circuit 104 can be included in an integrated circuit without the switching amplifier circuit 106.

During operation, the pulse modulation conversion module 102 receives a pulse code modulated signal 110 that includes audio information from a digital source 112. The digital source 112 can be a media file (e.g., an MP3 file), encoded audio information stored on a compact disc or other suitable storage medium, or any other suitable digital source. The pulse modulation conversion module 102 provides a pulse modulated signal 114 in response to the pulse code modulated signal 110. In some embodiments, the pulse modulated signal 114 can be pulse width modulated. In other embodiments, the pulse modulated signal 114 can be pulse density modulated. In addition, in some embodiments, the pulse modulated signal 114 can include a pair of pulse modulated signals.

The asynchronous error correction circuit 104 asynchronously provides a corrected pulse modulated signal 116 by selectively delaying and/or advancing an edge of the pulse modulated signal 114 based on the pulse modulated signal 114 and an amplified pulse modulated signal 118. By asynchronously providing the corrected pulse modulated signal 116, the asynchronous error correction circuit 104 can correct errors in pulse modulated signals having both a fixed switching frequency and a variable switching frequency, which is advantageous. As with the pulse modulated signal 114, the corrected pulse modulated signal 116 can include a pair of corrected pulse modulated signals in some embodiments.

The switching amplifier circuit 106 can be any suitable switching amplifier circuit such as, for example, a class D amplifier circuit. The switching amplifier circuit 106 provides the amplified pulse modulated signal 118 in response to the corrected pulse modulated signal 116. In some embodiments, the amplified pulse modulated signal 118 can include a pair of amplified pulse modulated signals. In such embodiments, the switching amplifier circuit 106 can include a pair of switching amplifier circuits if desired. The amplified pulse modulated signal 118 drives a load 120 such as a speaker or other suitable load. The amplified pulse modulated signal 118 is also fed back to the asynchronous error correction circuit 104 to provide the corrected pulse modulated signal 116.

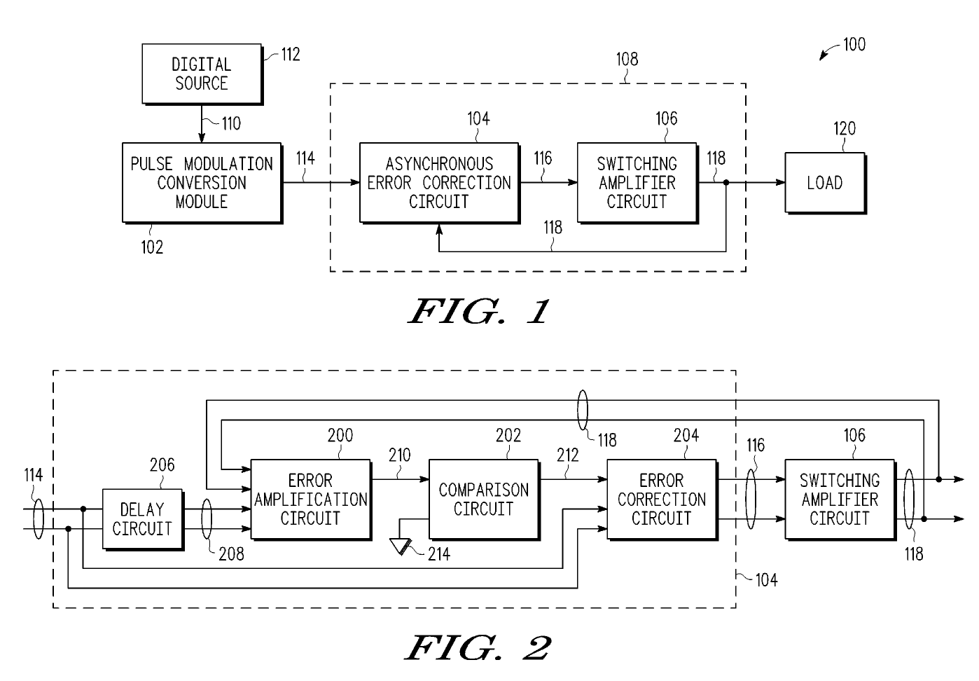

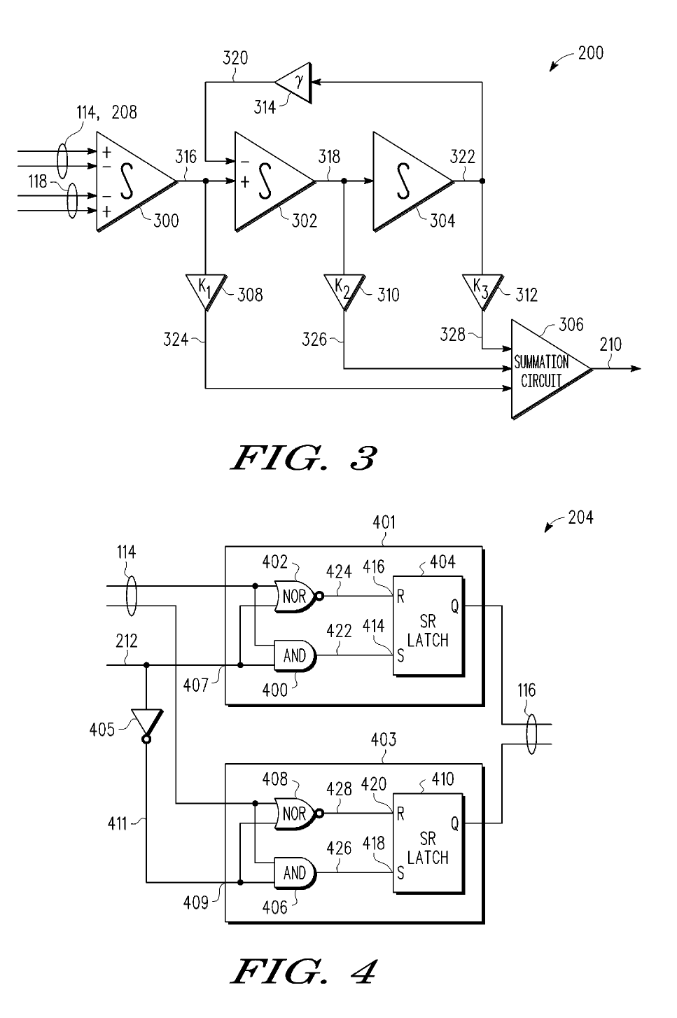

Referring now to FIG. 2, an exemplary functional block diagram of the asynchronous error correction circuit 104 is depicted. In this example, the pulse modulated signal 114, the corrected pulse modulated signal 116, and the amplified pulse modulated signal 118 each include pairs of respective signals. The asynchronous error correction circuit 104 includes an error amplification circuit 200, a comparison circuit 202, and an error correction circuit 204. The asynchronous error correction circuit 104 can also include a delay circuit 206 in some embodiments. The delay circuit 206 provides a time delayed pulse modulated signal 208 so that the pulse modulated signal 114 and the amplified pulse modulated signal 118 received by the error amplification circuit 200 are substantially time aligned with each other, thus providing compensation for delays associated with the switching amplifier circuit 106.

The error amplification circuit 200 provides an error signal 210 in response to the pulse modulated signal 114 and the amplified pulse modulated signal 118. The error signal 210 is based on an integration value determined by integrating a difference between the pulse modulated signal 114 (or the time delayed pulse modulated signal 208 in some embodiments) and the amplified pulse modulated signal 118.

The comparison circuit 202 provides a comparison signal 212 in response to the error signal 210 and a reference value 214. More specifically, the comparison circuit 202 compares the error signal 210 to the reference value 214 and provides the comparison signal 212 based thereon. When the error signal 210 is greater than the reference value 214 the comparison circuit 202 provides the comparison signal 212 representing a first logic state (e.g., logical 1). When the error signal 210 is less than the reference value 214 the comparison circuit 202 provides the comparison signal 212 representing a second logic state (e.g., logical 0). The reference value 214 represents a desired error value of the error signal 210 and can be any suitable value such as zero for example.

The error correction circuit 204 asynchronously provides the corrected pulse modulated signal 116 by selectively delaying and/or advancing an edge of pulse modulated signal 114 based on the comparison signal 212 and the pulse modulated signal 114. More specifically, the error correction circuit 204 transitions the corrected pulse modulated signal 116 from a first logic state (e.g., logical 0 or 1) to a second logic state (e.g., logical 1 or 0) in response to the pulse modulated signal 114 and the comparison signal 212 transitioning to a common logic state (e.g., both transitioning to the first or second logic state).

Referring now to FIG. 3, an exemplary functional block diagram of the error amplification circuit 200 is depicted. In this example, the pulse modulated signal 114 (or in some embodiments the time delayed pulse modulated signal 208) and the amplified pulse modulated signal 118 each include a respective pair of signals. The error amplification circuit 200 includes a first integration circuit 300, a second integration circuit 302, a third integration circuit 304, and a summation circuit 306. The error amplification circuit 200 can also include a first scaling circuit 308, a second scaling circuit 310, a third scaling circuit 312, and a fourth scaling circuit 314.

The first integration circuit 300 provides a first integration signal 316 in response to the pulse modulated signal 114 (or time delayed pulse modulated signal 208) and amplified pulse modulated signal 118. The first integration signal 316 is provided by integrating a difference between the pulse modulated signal 114 (or time delayed pulse modulated signal 208) and the amplified pulse modulated signal 118.

The second integration circuit 302 provides a second integration signal 318 in response to the first integration signal 316 and a scaling signal 320. The second integration signal 318 is provided by integrating a difference between the first integration signal 316 and the scaling signal 320.

The third integration circuit 304 provides a third integration signal 322 in response to the second integration signal 318. The third integration signal 322 is provided by integrating the second integration signal 318.

The fourth scaling circuit 314 provides the scaling signal 320 in response to the third integration signal 322. The scaling signal 320 is used to provide a non-DC pole in the frequency response of the error amplification circuit 200.

The first scaling circuit 308 scales the first integration signal 316 by a first value (e.g., k1) to provide a first modified integration signal 324. The second scaling circuit 310 scales the second integration signal 318 by a second value (e.g., k2) to provide a second modified integration signal 326. The third scaling circuit 312 scales the third integration signal 322 by a third value (e.g., k3) to provide a third modified integration signal 328.

The summation circuit 306 sums the first modified integration signal 324, the second modified integration signal 326, and the third modified integration signal 328 to provide the error signal 210. In some embodiments, the summation circuit 306 and comparison circuit 202 can be combined in a single summing comparator circuit (not shown).

Although the error amplification circuit 200 is a third order integrating amplification circuit in this example, skilled artisans will appreciated that higher or lower order integrating amplification circuits can be used.

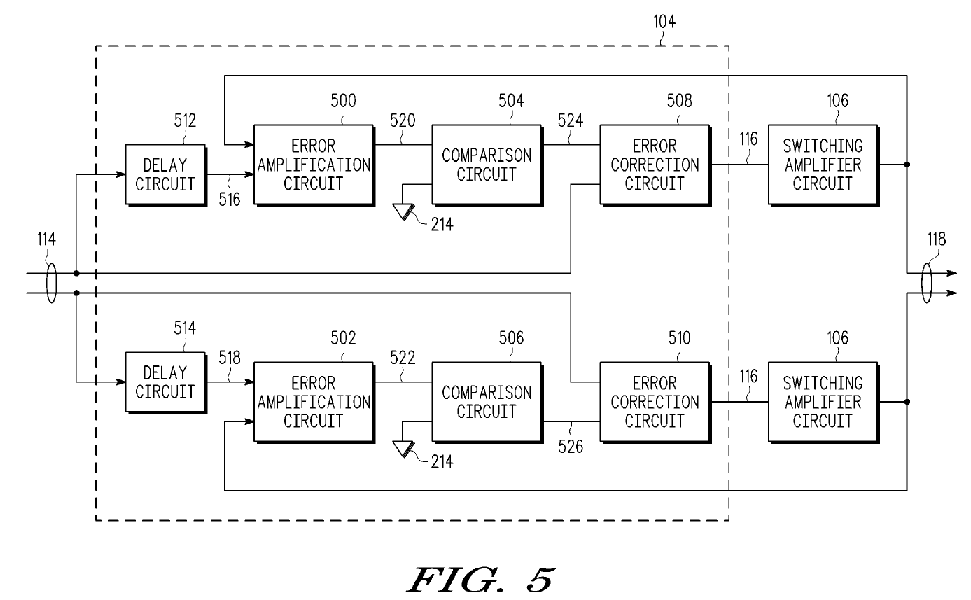

Referring now to FIG. 4, an exemplary functional block diagram of the error correction circuit 204 is depicted. In this example, the pulse modulated signal 114 and corrected pulse modulated signal 116 each include a pair of respective signals. The error correction circuit 204 includes a first correction circuit 401, a second correction circuit 403, and an inverter circuit 405. The inverter circuit 405 is operatively coupled between a respective input terminal 407, 409 of the first and second correction circuits 401, 403. The inverter circuit 405 provides an inverted comparison signal 411 in response to the comparison signal 212. As such, the inverted comparison signal 411 is complementary to the comparison signal 212.

During operation, the first correction circuit 401 provides a pulse edge transition of the corrected pulse modulated signal 116 in response to the pulse modulated signal 114 and the comparison signal 212 transitioning to a common logic state. In addition, the first correction circuit 401 reduces spurious transitions in the corrected pulse modulated signal 116. As such, the corrected pulse modulated signal 116 has substantially the same switching frequency as the pulse modulated input signal 114.

Similarly, the second correction circuit 403 provides a pulse edge transition of the corrected pulse modulated signal 116 in response to the pulse modulated signal 114 and the inverted comparison signal 411 transitioning to a common logic state. In addition, the second correction circuit 403 reduces spurious transitions in the corrected pulse modulated signal 116. As such, the corrected pulse modulated signal 116 has substantially the same switching frequency as the pulse modulated input signal 114.

The first correction circuit 401 includes a first logic circuit 400 such as an AND circuit, a second logic circuit 402 such as a NOR circuit, and a latch circuit 404 such as a set-reset latch circuit. The first logic circuit 400 is operatively coupled to a first input terminal 414 (e.g., set terminal) of the latch circuit 404. The second logic circuit 402 is operatively coupled to a second input terminal 416 (e.g., reset terminal) of the latch circuit 404.

The first logic circuit 400 provides a first latch input signal 422 (e.g., set) when the pulse modulated signal 114 and the comparison signal 212 are in a first logic state (e.g., logical 1). More specifically, the first logic circuit 400 provides the first latch input signal 422 when the pulse modulated signal 114 and the comparison signal 212 have the same polarity (e.g., positive) and are therefore in a common logic state.

The second logic circuit 402 provides a second latch input signal 424 (e.g., reset) when the pulse modulated signal 114 and the comparison signal 212 are in a second logic state (e.g., logical 0) that is complementary to the first logic state. More specifically, the second logic circuit 402 provides the second latch input signal 424 when the pulse modulated signal 114 and the comparison signal 212 have the same polarity (e.g., negative) and are therefore in a common logic state. The first latch circuit 404 provides a rising edge of the corrected pulse modulated signal 116 in response to the first latch input signal 422 and a falling edge of the corrected pulse modulated signal 116 in response to the second latch input signal 424.

The second correction circuit 403 includes third logic circuit 406 such as an AND circuit, a fourth logic circuit 408 such as a NOR circuit, and a second latch circuit 410 such as a set-reset latch circuit. The third logic circuit 406 is operatively coupled to a first input terminal 418 (e.g., set terminal) of the second latch circuit 410. The fourth logic circuit 408 is operatively coupled to a second input terminal 420 (e.g., reset terminal) of the second latch circuit 410.

The third logic circuit 406 provides a third latch input signal 426 (e.g., set) when the pulse modulated signal 114 and the inverted comparison signal 411 are in a first logic state (e.g., logical 1). More specifically, the third logic circuit 406 provides the third latch input signal 426 when the pulse modulated signal 114 and the inverted comparison signal 411 have the same polarity (e.g., positive) and are therefore in a common logic state.

The fourth logic circuit 408 provides a fourth latch input signal 428 (e.g., reset) when the pulse modulated signal 114 and the inverted comparison signal 411 are in a second logic state (e.g., logical 0) that is complementary to the first logic state. More specifically, the fourth logic circuit 408 provides the fourth latch input signal 428 when the pulse modulated signal 114 and the inverted comparison signal 411 have the same polarity (e.g., negative) and are therefore in a common logic state. The second latch circuit 410 provides a rising edge of the corrected pulse modulated signal 116 in response to the third latch input signal 426 and a falling edge of the corrected pulse modulated signal 116 in response to the fourth latch input signal 428.

In this manner, each correction circuit 401, 403 asynchronously provides a respective pair the corrected pulse modulated signal 116. Since the corrected pulse modulated signal 116 is provided asynchronously, the corrected pulse modulated signal 116 can have a fixed and/or variable switching frequency.

Referring now to FIG. 5, an alternate exemplary functional block diagram of the asynchronous error correction circuit 104 is depicted. In this example, the pulse modulated signal 114, the corrected pulse modulated signal 116, and the amplified pulse modulated signal 118 each include pairs of respective signals. The asynchronous error correction circuit 104 includes a first and second error amplification circuit 500, 502, a first and second comparison circuit 504, 506, a first and second error correction circuit 508, 510. The asynchronous error correction circuit 104 can also include a first and second delay circuit 512, 514 in some embodiments. The delay circuits 512, 514 provide respective time delayed pulse modulated signals 516, 518 so that the error amplification circuits 500, 502 can receive a respective pair of the pulse modulated signal 114 and the amplified pulse modulated signal 118 that are substantially aligned with each other, thus providing compensation for delays associated with the switching amplifier circuit 106.

Each error amplification circuit 500, 502 provides a respective error signal 520, 522 in response to the pulse modulated signal 114 and the amplified pulse modulated signal 118. Each of the error signals 520, 522 are based on an integration value determined by integrating a difference between the pulse modulated signal 114 (or the respective time delayed pulse modulated signal 516, 518 in some embodiments) and the amplified pulse modulated signal 118.

Each comparison circuit 504, 506 provides a respective comparison signal 524, 526 in response to the respective error signal 520, 522 and the reference value 214. More specifically, each comparison circuit 504, 506 compares the respective error signal 520, 522 to the reference value 214 and provides the respective comparison signal 524, 526 based thereon. When the respective error signal 520, 522 is greater than the reference value 214 the respective comparison circuit 504, 506 provides the respective comparison signal 524, 526 representing a first logic state (e.g., logical 1). When the respective error signal 520, 522 is less than the reference value 214 the respective comparison circuit 504, 506 provides the respective comparison signal 524,526 representing a second logic state (e.g., logical 0). As previously noted, the reference value 214 represents a desired error value of the error signals 520, 522 and can be any suitable value such as zero for example.

Each error correction circuit 508, 510 asynchronously provides a respective pair of the corrected pulse modulated signal 116 by selectively delaying and/or advancing an edge of pulse modulated signal 114 based on the respective comparison signal 524, 526 and the pulse modulated signal 114.

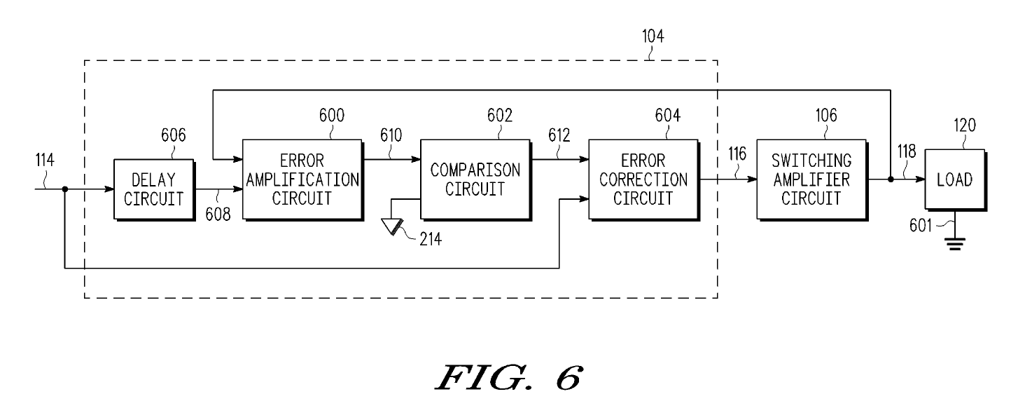

Referring now to FIG. 6, another exemplary functional block diagram of the asynchronous error correction circuit 104 is depicted. In this example, the pulse modulated signal 114, the corrected pulse modulated signal 116, and the amplified pulse modulated signal 118 are not paired signals. As such, the load 120 is operatively coupled to ground 601 in this example.

The asynchronous error correction circuit 104 includes an error amplification circuit 600, a comparison circuit 602, and an error correction circuit 604. The asynchronous error correction circuit 104 can also include a delay circuit 606 in some embodiments. The delay circuit 606 provides a time delayed pulse modulated signal 608 so that the error amplification circuit 600 can receive the pulse modulated signal 114 and the amplified pulse modulated signal 118 that are substantially aligned with each other, thus providing compensation for delays associated with the switching amplifier circuit 106.

The error amplification circuit 600 provides an error signal 610 in response to the pulse modulated signal 114 and the amplified pulse modulated signal 118. The error signal 610 is based on an integration value determined by integrating a difference between the pulse modulated signal 114 (or the time delayed pulse modulated signal 608 in some embodiments) and the amplified pulse modulated signal 118.

The comparison circuit 602 provides a comparison signal 612 in response to the error signal 610 and the reference value 214. More specifically, the comparison circuit 602 compares the error signal 610 to the reference value 214 and provides the comparison signal 612 based thereon.

The correction circuit 604 asynchronously provides the corrected pulse modulated signal 116 by selectively delaying and/or advancing an edge of pulse modulated signal 114 based on the comparison signal 612 and the pulse modulated signal 114.

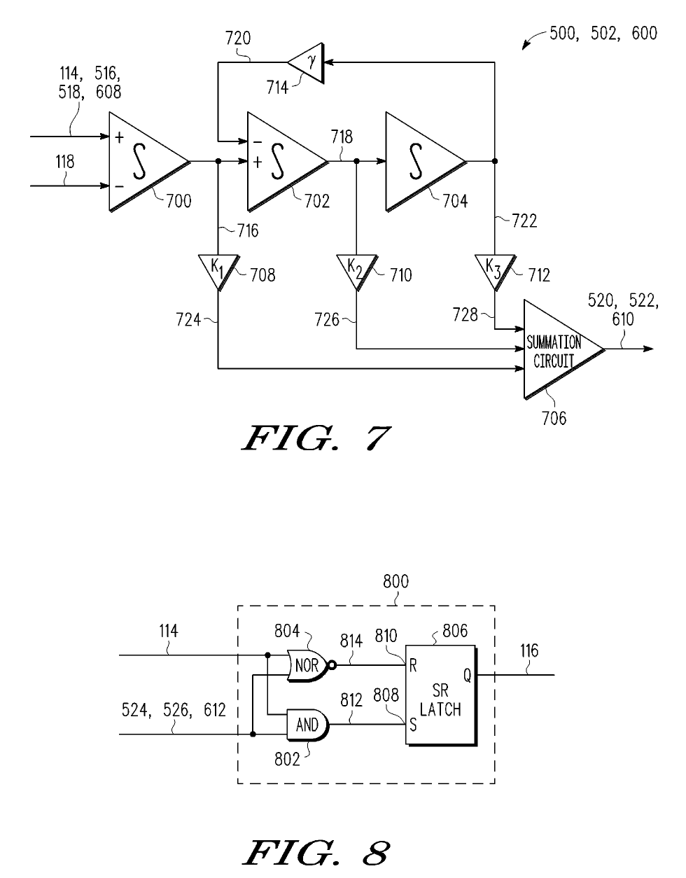

Referring now to FIG. 7, an exemplary functional block diagram of the error amplification circuit 500, 502, 600 is depicted. The error amplification circuit 500, 502, 600 includes a first integration circuit 700, a second integration circuit 702, a third integration circuit 704, and a summation circuit 706. The error amplification circuit 500, 502, 600 can also include a first scaling circuit 708, a second scaling circuit 710, a third scaling circuit 712, and a fourth scaling circuit 714.

The first integration circuit 700 provides a first integration signal 716 in response to the pulse modulated signal 114 (or the respective time delayed pulse modulated signal 516, 518, 608) and amplified pulse modulated signal 118. The first integration signal 716 is provided by integrating a difference between the pulse modulated signal 114 (or the respective time delayed pulse modulated signal 516, 518, 608) and the amplified pulse modulated signal 118.

The second integration circuit 702 provides a second integration signal 718 in response to the first integration signal 716 and a scaling signal 720. The second integration signal 718 is provided by integrating a difference between the first integration signal 716 and the scaling signal 720.

The third integration circuit 704 provides a third integration signal 722 in response to the second integration signal 718. The third integration signal 718 is provided by integrating the second integration signal 718.

The scaling circuit 714 provides the scaling signal 720 in response to the third integration signal 722. The scaling signal 720 is used to provide a non-DC pole in the frequency response of the error amplification circuit 500, 502, 600.

The first scaling circuit 708 scales the first integration signal 716 by a first value (e.g., k1) to provide a first modified integration signal 724. The second scaling circuit 710 scales the second integration signal 718 by a second value (e.g., k2) to provide a second modified integration signal 726. The third scaling circuit 712 scales the third integration signal 722 by a third value (e.g., k3) to provide a third modified integration signal 728.

The summation circuit 706 sums the first modified integration signal 724, the second modified integration signal 726, and the third modified integration signal 728 to provide the error signal 520, 522, 610. In some embodiments, the summation circuit 706 can be combined with the comparison circuit 504, 506, 602 to form a summing comparator circuit having a combined functionality of the summation circuit 706 and the comparison circuit 504, 506, 602.

Although the error amplification circuit 500, 502, 600 is a third order integrating amplification circuit in this example, skilled artisans will appreciated that higher or lower order integrating amplification circuits can be used.

Referring now to FIG. 8, an exemplary functional block diagram of the error correction circuit 508, 510, 604 is depicted. The error correction circuit 508, 510, 604 includes a correction circuit 800. During operation, the correction circuit 800 provides a pulse edge transition of the corrected pulse modulated signal 116 in response to the pulse modulated signal 114 and comparison signals 524, 526, 612 transitioning to a common logic state. The correction circuit 800 reduces spurious transitions in the corrected pulse modulated signal 116. As such, the corrected pulse modulated signal 116 has substantially the same switching frequency as the pulse modulated input signal 114.

The correction circuit 800 includes a first logic circuit 802 such an AND circuit, a second logic circuit 804 such as a NOR circuit, and a latch circuit 806 such as a set-reset latch circuit. The first logic circuit 802 is operatively coupled to a first input terminal 808 (e.g., set terminal) of the latch circuit 806. The second logic circuit 804 is operatively coupled to a second input terminal 810 (e.g., reset terminal) of the latch circuit 806.

The first logic circuit 802 provides a first latch input signal 812 (e.g., set) when the pulse modulated signal 114 and the comparison signal 524, 526, 612 are in a first logic state (e.g., logical 1). More specifically, the first logic circuit 802 provides the first latch input signal 812 when the pulse modulated signal 114 and the comparison signal 524, 526, 612 have the same polarity (e.g., positive) and are therefore in a common logic state.

The second logic circuit 804 provides a second latch input signal 814 (e.g., reset) when the pulse modulated signal 114 and the comparison signal 524, 526, 612 are in a second logic state (e.g., logical 0) that is complementary to the first logic state. More specifically, the second logic circuit 804 provides the second latch input signal 814 when the pulse modulated signal 114 and the comparison signal 524, 526, 612 have the same polarity (e.g., negative) and are therefore in a common logic state. The latch circuit 806 provides a rising edge of the corrected pulse modulated signal 116 in response to the first latch input signal 812 and a falling edge of the corrected pulse modulated signal 116 in response to the second latch input signal 814.

As noted above, among other advantages, the asynchronous error correction circuit 104 compensates for switching amplifier nonlinearities and power supply noise errors of variable and fixed switching frequency pulse modulated signals. In addition, the asynchronous error correction circuit 104 does not require an analog to digital converter circuit to compensate for nonlinearities and power supply noise errors. As such, the overall size of the circuit is reduced.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims. In addition, unless stated otherwise, terms such as “first” and “second” are used to arbitrarily distinguish between the elements such terms describe. Thus, these terms are not necessarily intended to indicate temporal or other prioritization of such elements. The term coupled, as used herein, is defined as connected, although not necessarily directly, and not necessarily mechanically. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. The terms a or an, as used herein, are defined as one or more than one.

What is claimed is:

1. A circuit, comprising:
a comparison circuit that is operative to provide a comparison signal in response to an error value and a reference value, wherein the error value is based on a pulse modulated input signal and a pulse modulated output signal; and
a correction circuit that is operative to asynchronously provide a corrected pulse modulated signal by selectively delaying and advancing an edge of the pulse modulated input signal based on the comparison signal, wherein the pulse modulated output signal is based on the corrected pulse modulated signal.

2. The circuit of claim 1 wherein the correction circuit is operative to transition the corrected pulse modulated signal from a first logic state to a second logic state in response to the pulse modulated input signal and the comparison signal transitioning to a common logic state.

3. The circuit of claim 1 wherein the correction circuit comprises a latch circuit that is operative to one of delay and advance the edge of the pulse modulated input signal in response to the pulse modulated input signal and the comparison signal.

4. The circuit of claim 3 wherein the correction circuit further comprises:
a first logic circuit, operatively coupled to a first input terminal of the latch circuit, that is operative to provide a first latch input signal when an input value of the pulse modulated input signal and the comparison signal are in a first logic state; and
a second logic circuit, operatively coupled to a second input terminal of the latch circuit, that is operative to provide a second latch input signal when the input value of the pulse modulated input signal and the comparison signal are in a second logic state that is complementary to the first logic state.

5. The circuit of claim 4 wherein the latch circuit is operative to provide a rising edge of the corrected pulse modulated signal in response to the first latch input signal and a falling edge of the corrected pulse modulated signal in response to the second latch input signal.

6. The circuit of claim 1 wherein the error value is based on an integration value determined by integrating a difference between the pulse modulated input signal and the pulse modulated output signal.

7. The circuit of claim 1 further comprising an error amplification circuit that is operative to provide the error value in response to the pulse modulated input signal and the pulse modulated output signal.

8. The circuit of claim 1 further comprising a switching amplifier circuit that is operative to provide the pulse modulated output signal in response to the corrected pulse modulated signal.

9. The circuit of claim 1 further comprising:
a second comparison circuit that is operative to provide a second comparison signal in response to a second error value and the reference value, wherein the second error value is based on a second pulse modulated input signal and a second pulse modulated output signal; and
a second correction circuit that is operative to asynchronously provide a second corrected pulse modulated signal by selectively delaying and advancing a second edge of the second pulse modulated input signal based on the second comparison signal, wherein the second pulse modulated output signal is based on the second corrected pulse modulated signal.

10. The circuit of claim 9 further comprising an inverter circuit, operatively coupled between the correction circuit and the second correction circuit, that is operative to provide an inverted comparison signal to the second correction circuit in response to the comparison signal.

11. An integrated circuit, comprising:
an asynchronous error correction circuit that comprises:
a comparison circuit that is operative to provide a comparison signal in response to an error value and a reference value, wherein the error value is based on a pulse modulated input signal and a pulse modulated output signal; and
a correction circuit that is operative to asynchronously provide a corrected pulse modulated signal by selectively delaying and advancing an edge of the pulse modulated input signal based on the comparison signal, wherein the pulse modulated output signal is based on the corrected pulse modulated signal.

12. The integrated circuit of claim 11 wherein the correction circuit is operative to transition the corrected pulse modulated signal from a first logic state to a second logic state in response to the pulse modulated input signal and the comparison signal transitioning to a common logic state.

13. The integrated circuit of claim 11 wherein the correction circuit comprises a latch circuit that is operative to one of delay and advance the edge of the pulse modulated input signal in response to the pulse modulated input signal and the comparison signal.

14. The integrated circuit of claim 13 wherein the correction circuit further comprises:
a first logic circuit, operatively coupled to a first input terminal of the latch circuit, that is operative to provide a first latch input signal when an input value of the pulse modulated input signal and the comparison signal are in a first logic state; and
a second logic circuit, operatively coupled to a second input terminal of the latch circuit, that is operative to provide a second latch input signal when the input value of the pulse modulated input signal and the comparison signal are in a second logic state that is complementary to the first logic state.

15. The integrated circuit of claim 14 wherein the latch circuit is operative to provide a rising edge of the corrected pulse modulated signal in response to the first latch input signal and a falling edge of the corrected pulse modulated signal in response to the second latch input signal.

16. The integrated circuit of claim 11 further comprising an error amplification circuit that is operative to provide the error value in response to the pulse modulated input signal and the pulse modulated output signal.

17. The integrated circuit of claim 11 further comprising a switching amplifier circuit that is operative to provide the pulse modulated output signal in response to the corrected pulse modulated signal.

18. An audio device, comprising:
a conversion circuit that is operative to provide a pulse width modulated signal in response to a pulse code modulated signal;
an error correction circuit that comprises:
a comparison circuit that is operative to provide a comparison signal in response to an error value and a reference value, wherein the error value is based on the pulse width modulated signal and a pulse width modulated output signal; and
a correction circuit that is operative to asynchronously provide a corrected pulse width modulated signal by selectively delaying and advancing an edge of the pulse width modulated signal based on the comparison signal, wherein the pulse width modulated output signal is based on the corrected pulse width modulated signal; and
a switching amplifier circuit that is operative to provide the pulse width modulated output signal in response to the corrected pulse width modulated signal.

19. The audio device of claim 18 wherein the correction circuit is operative to transition the corrected pulse width modulated signal from a first logic state to a second logic state in response to the pulse width modulated signal and the comparison signal transitioning to a common logic state.

20. The audio device of claim 18 wherein the correction circuit comprises:
a latch circuit that is operative to one of delay and advance the edge of the pulse width modulated signal in response to the pulse width modulated signal and the comparison signal;
a first logic circuit, operatively coupled to a first input terminal of the latch circuit, that is operative to provide a first latch input signal when an input value of the pulse width modulated signal and the comparison signal are in a first logic state; and
a second logic circuit, operatively coupled to a second input terminal of the latch circuit, that is operative to provide a second latch input signal when the input value of the pulse width modulated signal and the comparison signal are in a second logic state that is complementary to the first logic state, wherein the latch circuit is operative to provide a rising edge of the corrected pulse width modulated signal in response to the first latch input signal and a falling edge of the corrected pulse width modulated signal in response to the second latch input signal.
